(19) United States
(12) Patent Application Publication
(10) Pub. No.: US 2026/0142132 A1
(43) Pub. Date: May 21, 2026

(54) PLASMA PROCESSING APPARATUS

(71) Applicant: INDUSTRIAL TECHNOLOGY RESEARCH INSTITUTE, Hsinchu (TW)

(72) Inventors: Hsuan-Fu WANG, Hsinchu City (TW); Chih-Hung LIU, Hsinchu City (TW); Chia-Hao CHANG, Hsinchu County (TW); Yi-Jiun LIN, Hsinchu County (TW); Ching-Chiun WANG, Miaoli County (TW)

(73) Assignee: INDUSTRIAL TECHNOLOGY RESEARCH INSTITUTE, Hsinchu (TW)

(21) Appl. No.: 18/985,186

(22) Filed: Dec. 18, 2024

(30) Foreign Application Priority Data
Nov. 18, 2024 (TW) 113144303

(51) Int. Cl. H01J 37/32

(52) U.S. Cl. CPC H01J 37/32623; H01J 37/32834; H01J 2237/3323

(57) ABSTRACT

This disclosure relates to a plasma processing apparatus including a lower chamber, an upper chamber and a dispensing plate. The lower chamber is configured for a sample to be placed therein. The upper chamber is located above the lower chamber. The upper chamber is configured to accommodate a plasma. The dispensing plate is disposed between the lower chamber and the upper chamber. The dispensing plate includes a dielectric material layer, a metal material layer and a through hole. The metal material layer is disposed on a side of the dielectric material layer close to the lower chamber. The through hole is arranged through the dielectric material layer and the metal material layer along a longitudinal direction. The through hole is in fluid communication connection with the lower chamber and the upper chamber. The through hole is configured for the plasma passing therethrough to be deposited onto the sample.

### CROSS-REFERENCE TO RELATED APPLICATIONS

This non-provisional application claims priority under 35 U.S.C. § 119(a) on Patent Application No(s). 113144303 filed in Taiwan on November 18, 2024, the entire contents of which are hereby incorporated by reference.

### TECHNICAL FIELD

The present disclosure relates to a plasma processing apparatus, more particularly to a plasma processing apparatus having a dispensing plate with a specific size ratio.

### BACKGROUND

In semiconductor manufacturing processes, plasma is extensively utilized for surface treatments, with plasma deposition being one of the most commonly employed techniques.

However, plasma consists of charged particles that are highly susceptible to some ambient electric fields during deposition. This susceptibility can lead to deviations in the deposition path, causing uneven plasma distribution in the deposition. Consequently, developing an apparatus that ensures uniform plasma deposition has become a top issue in this field.

### SUMMARY

According to one aspect of the present disclosure, a plasma processing apparatus includes a lower chamber, an upper chamber and a dispensing plate. The lower chamber is configured for a sample to be placed therein. The upper chamber is located above the lower chamber. The upper chamber is configured to accommodate a plasma. The dispensing plate is disposed between the lower chamber and the upper chamber. The dispensing plate includes a dielectric material layer, a metal material layer and at least one through hole. The metal material layer is disposed on a side of the dielectric material layer close to the lower chamber. The at least one through hole is arranged through the dielectric material layer and the metal material layer along a longitudinal direction. The at least one through hole is in fluid communication connection with the lower chamber and the upper chamber. The at least one through hole is configured for the plasma passing therethrough to be deposited onto the sample. When a first thickness of the dielectric material layer along the longitudinal direction is defined as T1, a second thickness of the metal material layer along the longitudinal direction is defined as T2, and a diameter of the at least one through hole is defined as D1, the following condition is satisfied: 5≤(T1+T2)/D1.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a schematic view of a plasma processing apparatus according to one embodiment of the present disclosure;

FIG. 2 is a perspective view of a dispensing plate of the plasma processing apparatus in FIG. 1;

FIG. 3 is a top view of the dispensing plate of the plasma processing apparatus in FIG. 2;

FIG. 4 is a cross-sectional view of a part of the dispensing plate of the plasma processing apparatus in FIG. 2;

FIG. 5 to FIG. 6 are simulation diagrams illustrating plasma deposition of the plasma processing apparatus in FIG. 1;

FIG. 7 to FIG. 8 are simulation diagrams illustrating plasma deposition of a plasma processing apparatus not belonging to the present disclosure;

FIG. 9 is a simulation diagram illustrating plasma deposition of the plasma processing apparatus in FIG. 1;

FIG. 10 is a simulation diagram illustrating plasma deposition of a plasma processing apparatus not belonging to the present disclosure;

FIG. 11 is a simulation diagram illustrating plasma deposition of the plasma processing apparatus in FIG. 1; and

FIG. 12 is a simulation diagram illustrating plasma deposition of a plasma processing apparatus not belonging to the present disclosure.

### DETAILED DESCRIPTION

Aspects and advantages of the invention will become apparent from the following detailed descriptions with the accompanying drawings. For purposes of explanation, one or more specific embodiments are given to provide a thorough understanding of the invention, and which are described in sufficient detail to enable one skilled in the art to practice the described embodiments. It should be understood that the following descriptions are not intended to limit the embodiments to one specific embodiment. On the contrary, it is intended to cover alternatives, modifications, and equivalents as can be included within the spirit and scope of the described embodiments as defined by the appended claims.

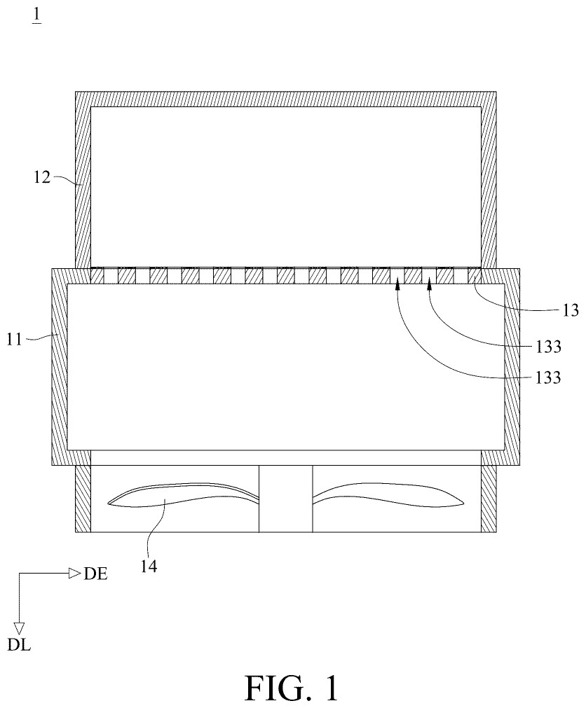

In the following, a plasma processing apparatus according to one embodiment of the present disclosure would be illustrated. Please refer to FIG. 1, which is a schematic view of a plasma processing apparatus according to one embodiment of the present disclosure.

A plasma processing apparatus 1 provided in this embodiment includes a lower chamber 11, an upper chamber 12 and a dispensing plate 13.

The lower chamber 11 is configured for a sample (not shown in the drawings) to be placed therein. The upper chamber 12 is located above the lower chamber 11, and the upper chamber 12 is configured to accommodate a plasma (not shown in the drawings). The dispensing plate 13 is disposed between the lower chamber 11 and the upper chamber 12. In some cases, the dispensing plate 13 may be called as “shower head” or “sprinkler head”. Please be noted that the size of the lower chamber 11, the upper chamber 12 and the dispensing plate 13 may be different depending on requirements, and the present disclosure is not limited thereto.

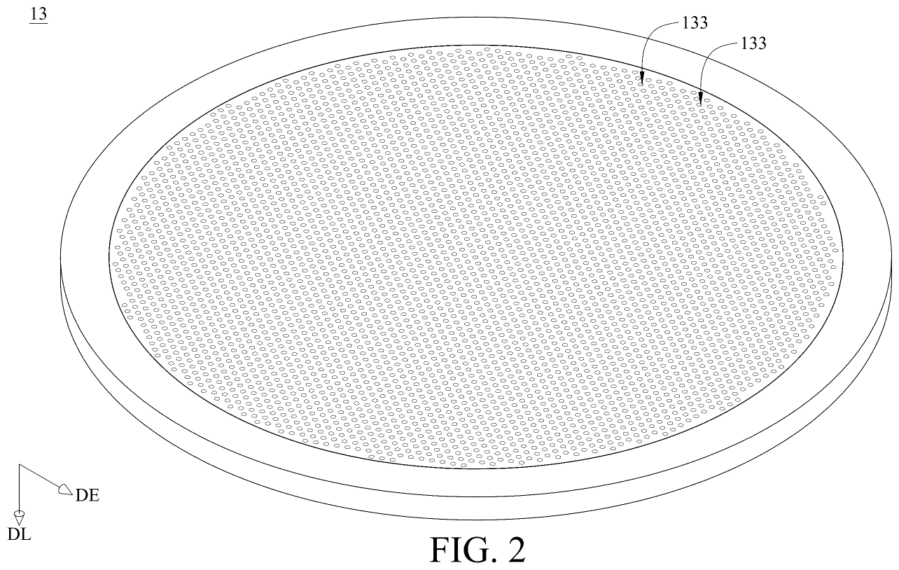

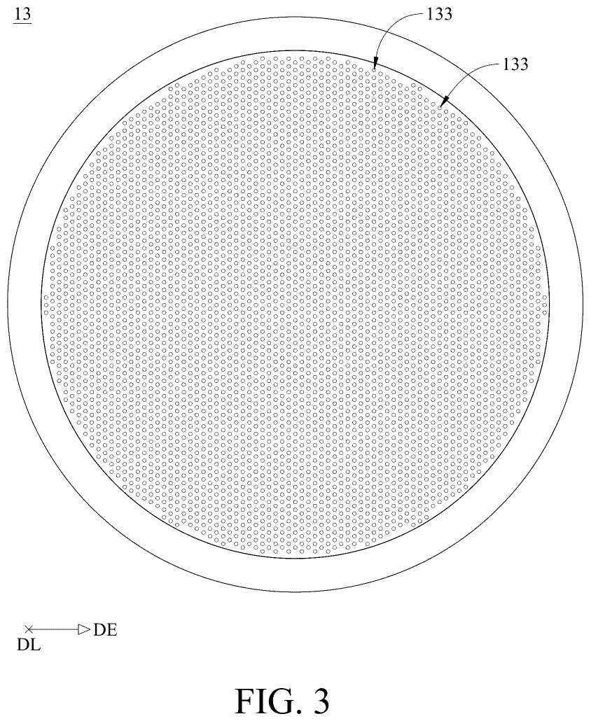

Then, please refer to FIG. 2 to FIG. 3 with reference to FIG. 1, where FIG. 2 is a perspective view of a dispensing plate of the plasma processing apparatus in FIG. 1, and FIG. 3 is a top view of the dispensing plate of the plasma processing apparatus in FIG. 2.

As shown in FIG. 2 and FIG. 3, the dispensing plate 13 may be in a disc shape, but the present disclosure is not limited thereto. In some embodiments of the present disclosure, the dispensing plate may be a quadrilateral disk, a pentagonal disk or other polygonal disk. In this embodiment, the dispensing plate 13 includes a dielectric material layer 131, a metal material layer 132 and a plurality of through holes 133. The dielectric material layer 131 may extend along an extension direction DE parallel to a horizontal direction. The metal material layer 132 is disposed on a side of the dielectric material layer 131 close to the lower chamber 11; that is, the metal material layer 132 is located close to the lower chamber 11 where the sample is placed than the dielectric material layer 131; it can also be considered that the metal material layer 132 is disposed below the dielectric material layer 131. The through holes 133 are arranged through the dielectric material layer 131 and the metal material layer 132 along a longitudinal direction DL. The through holes 133 are in fluid communication connection with the lower chamber 11 and the upper chamber 12. Please be noted that the longitudinal direction DL as mentioned above refers to an overall passing direction of one through hole 133. Please be noted that the quantity and the shapes of the through holes 133 are not intended to restrict the present disclosure.

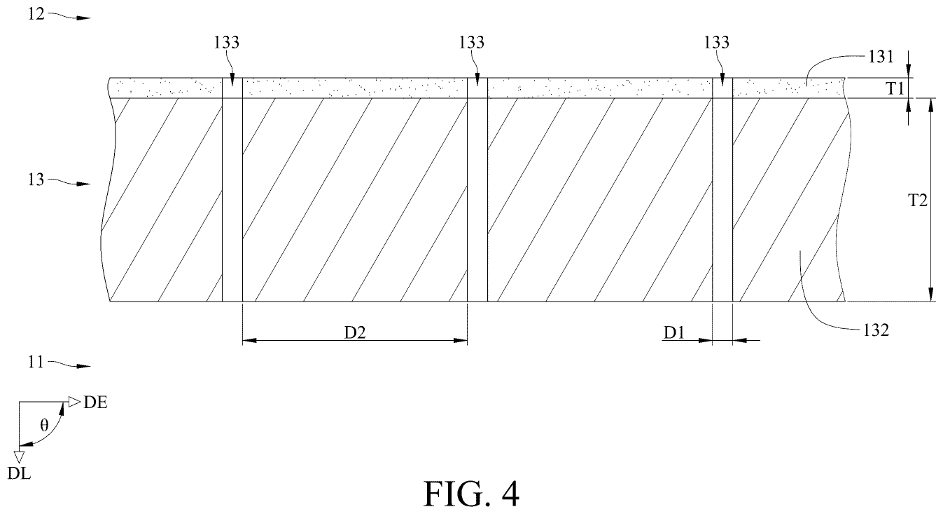

The through holes 133 are configured for the plasma passing therethrough to be deposited onto the sample. As the plasma passes through the through holes 133, the plasma is electrically neutralized through the action of dielectric material layer 131, and then the plasma is collimated through the action of the metal material layer 132 before being uniformly deposited onto the sample in the lower chamber 11. The arrangement of the dielectric material layer 131, the metal material layer 132 and the through holes 133 of the dispensing plate 13 influences the deposition of the plasma. Please refer to FIG. 4 with reference to FIG. 1 to FIG. 3, where FIG. 4 is a cross-sectional view of a part of the dispensing plate of the plasma processing apparatus in FIG. 2.

When a first thickness of the dielectric material layer 131 along the longitudinal direction DL is defined as T1, a second thickness of the metal material layer 132 along the longitudinal direction DL is defined as T2, and a diameter of each through hole 133 is defined as D1, the following condition is satisfied: 5≤(T1+T2)/D1. Therefore, it is favorable to prevent the plasma from generating a turbulent flow in the lower chamber 11. Moreover, the following condition can also be satisfied: 5≤(T1+T2)/D1≤2. Therefore, it is favorable to prevent affecting deposition quality caused by the plasma entering the lower chamber 11 too sparse. Please be noted that the thicknesses T1 and T2 are defined along the longitudinal direction DL; that is, the values of the thicknesses T1 and T2 of the dispensing plate 13 may vary in different scenarios, depending on whether the through holes are arranged perpendicularly or non-perpendicularly through the dielectric material layer and the metal material layer. Please be noted that the diameter D1 is defined as the distance between two farthest points on the cross-section of each through hole, in cases where the cross-section of the through hole is non-circular.

When the first thickness is defined as T1, and the second thickness is defined as T2, the following condition can be satisfied: T1≤T2. Therefore, it is favorable to further enhance the collimation of the depositing plasma.

When the first thickness is defined as T1, and the diameter is defined as D1, the following condition can be satisfied: D1≤10×T1. Therefore, it is favorable to ensure adequate electrical neutralization of the plasma.

When an angle between the longitudinal direction DL and the extension direction DE is defined as θ, the following condition can be satisfied: 75°≤θ≤105°. Therefore, it is favorable to prevent excessive angular deviation of the plasma streams after passing through the through holes 133, thereby ensuring uniform plasma deposition. Moreover, the following condition can also be satisfied: θ=90°. Therefore, it is favorable to aligning the collimated plasma deposition with the direction of gravity, thereby improving deposition uniformity.

When the diameter is defined as D1, and an interval distance between adjacent two of the through holes 133 is defined as D2, the following condition can be satisfied: D2≤20×D1. Therefore, it is favorable to prevent interference between plasma streams exiting adjacent through holes 133.

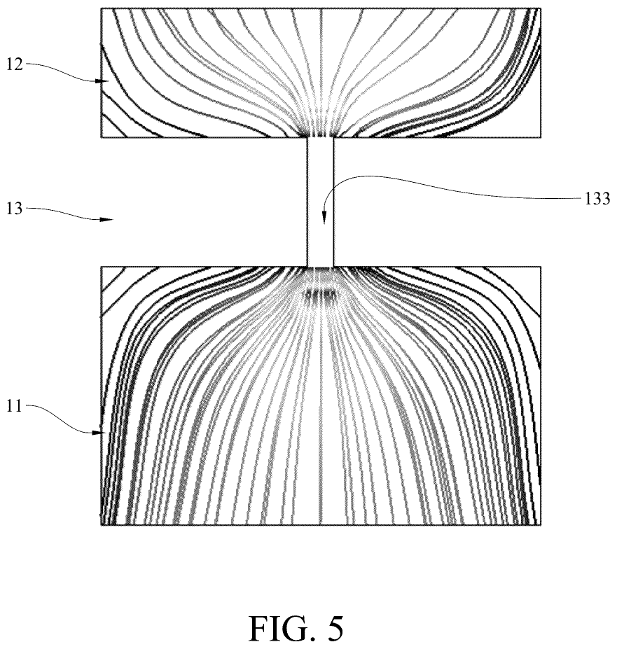

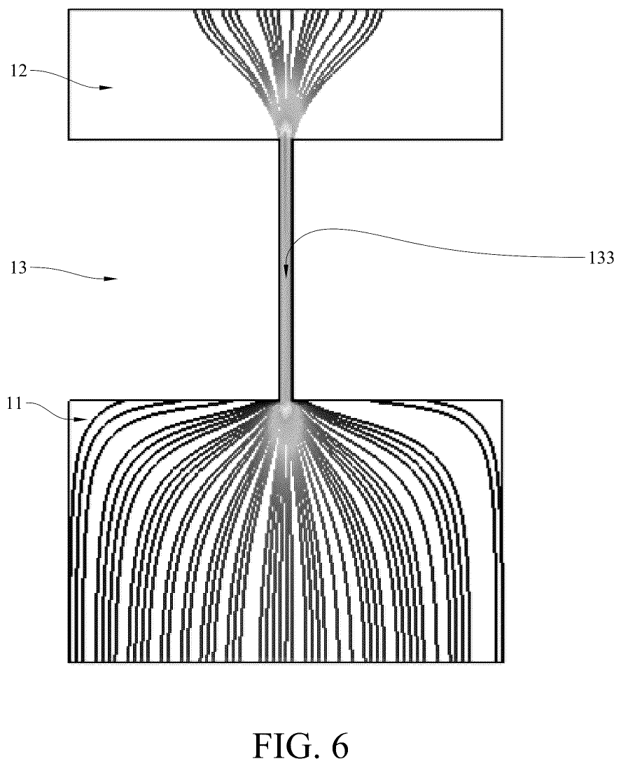

Please refer to FIG. 5 to FIG. 6 with reference to FIG. 1 to FIG. 4, where FIG. 5 to FIG. 6 are simulation diagrams illustrating plasma deposition of the plasma processing apparatus in FIG. 1, corresponding to (T1+T2)/D1 values of 5 and 20, respectively. When (T1+T2)/D1=5, as shown in FIG. 5, the plasma exiting the through holes 133 forms a collimated flow field, enabling uniform deposition onto the sample in the lower chamber 11. When (T1+T2)/D1=20, as shown in FIG. 6, the plasma exiting the through holes 133 retains a collimated flow field but with a relatively slow deposition speed, making it suitable for applications requiring slow deposition.

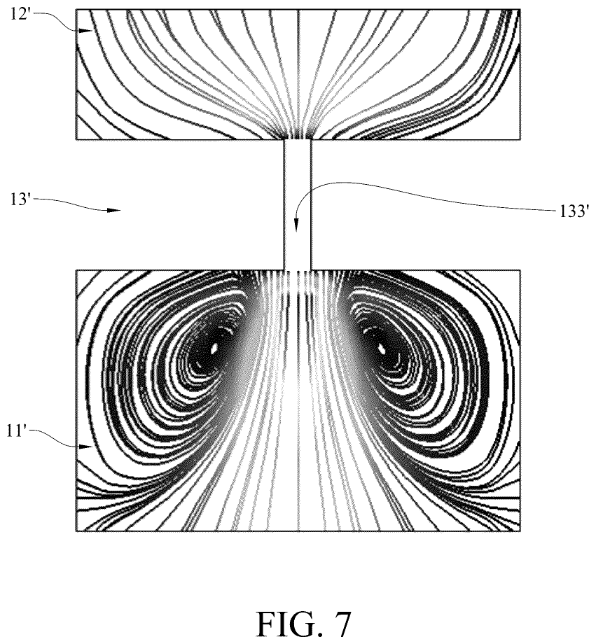

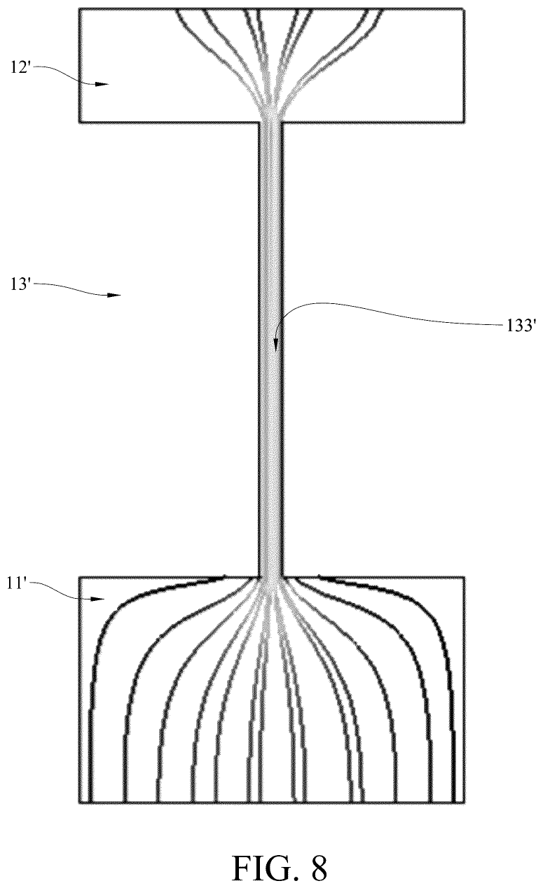

In contrast, please refer to FIG. 7 to FIG. 8, which are simulation diagrams illustrating plasma deposition of a plasma processing apparatus not belonging to the present disclosure, corresponding to (T1+T2)/D1 values of 4.9 and 20.1, respectively. When (T1+T2)/D1=4.9, as shown in FIG. 7, the insufficient thicknesses lead to inadequate electrical neutrality of the plasma exiting from the upper chamber 12′ through the through holes 133′ of the dispensing plate 13′. This results in turbulence in the lower chamber 11′, adversely affecting deposition quality. When (T1+T2)/D1=20.1, as shown in FIG. 8, the excessive thicknesses cause only a small amount of plasma to exit the through holes 133′ of the dispensing plate 13′ from the upper chamber 12′. This results in a sparse deposition flow field in the lower chamber 11′, negatively impacting deposition uniformity.

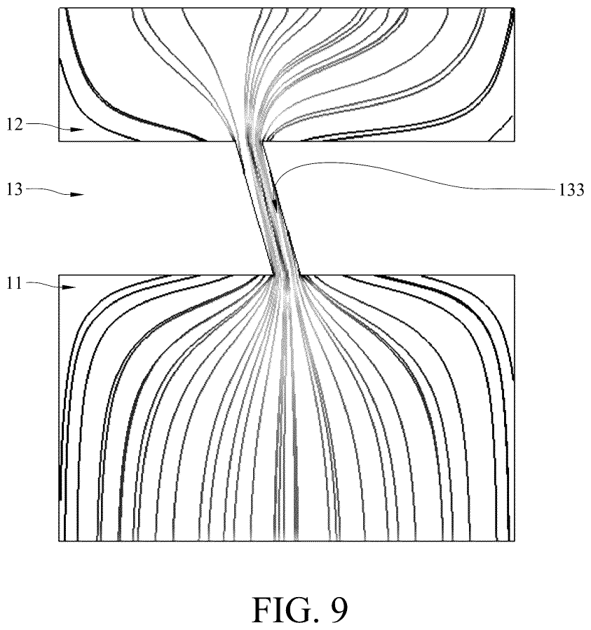

Please refer back to FIG. 5 to FIG. 6, which are simulation diagrams illustrating plasma deposition of the plasma processing apparatus in FIG. 1, where the value of θ is 90°. When θ=90°, as shown in FIG. 5 to FIG. 6, the plasma exiting the through holes 133 forms a vertically descending flow field, enabling uniform deposition onto the sample in the lower chamber 11. Please refer to FIG. 9, which is a simulation diagram illustrating plasma deposition of the plasma processing apparatus in FIG. 1, where the value of θ is 75°. When θ=75°, as shown in FIG. 9, the plasma exiting the through holes 133 maintains a vertically descending flow field, thereby ensuring uniform deposition onto the sample in the lower chamber 11. Please be noted that θ=105°may also be interpreted in FIG. 9, depending on the reference horizontal base used.

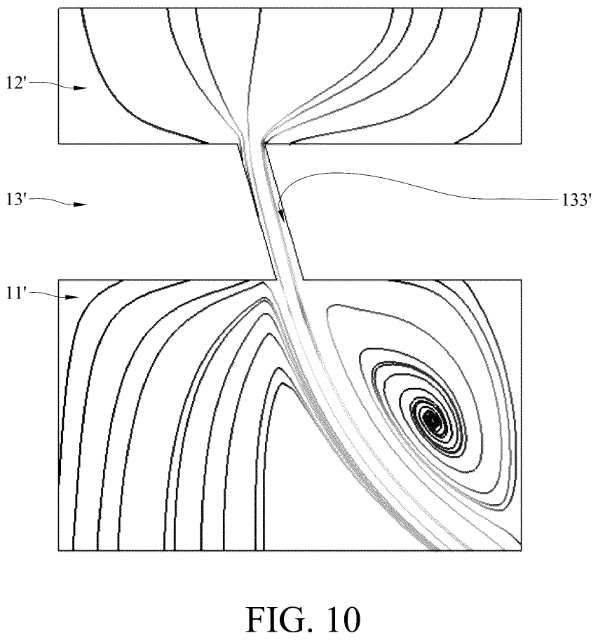

In contrast, please refer to FIG. 10, which is a simulation diagram illustrating plasma deposition of a plasma processing apparatus not belonging to the present disclosure, where the value of θ is 74°. When θ=74°, as shown in FIG. 10, the excessive inclination causes the plasma to flow obliquely after it exits from the upper chamber 12′ through the through holes 133′ of the dispensing plate 13′, negatively impacting deposition uniformity of the plasma in the lower chamber 11′.

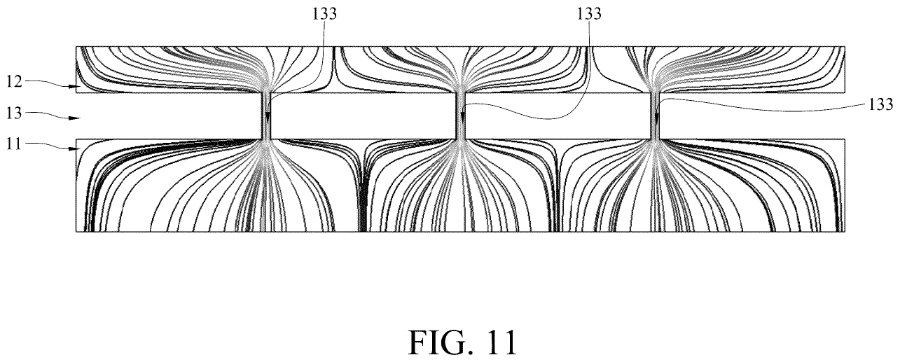

Please refer to FIG. 11, which is a simulation diagram illustrating plasma deposition of the plasma processing apparatus in FIG. 1, where the value of D2 is 20 times that of D1. When D2 is 20 times D1, as shown in FIG. 11, the plasma exiting the through holes 133 has a collimated flow field to be uniformly deposited onto the sample in the lower chamber 11.

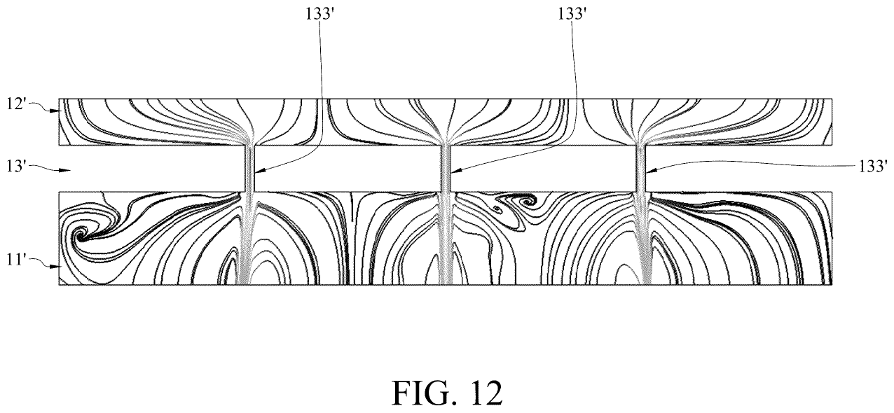

In contrast, please refer to FIG. 12, which is a simulation diagram illustrating plasma deposition of a plasma processing apparatus not belonging to the present disclosure, where the value of D2 is 20.1 times that of D1. When D 2 is 20 times greater than D1, as shown in FIG. 12, the excessive intervals between the through holes 133′ of the dispensing plate 13′ cause over-dispersion of the plasma exiting from the upper chamber 12′ through the through holes 133′. This results in turbulence in the lower chamber 11′, negatively impacting deposition uniformity.

In this embodiment, a ratio of a sum of areas of the through holes 133 to an area of the dielectric material layer 131 ranges from 15% to 40%; for example, as illustrated in FIG. 2, the ratio of the total area of the through holes 133 to the area of the dielectric material layer 131 is 22%. Such a design ensures adequate plasma flows from the upper chamber 12 into the lower chamber 11.

In this embodiment, the plasma processing apparatus 1 may further include an extractor pump 14 that can be in fluid communication connection with the lower chamber 11 for extracting air from the lower chamber 11. Therefore, it is favorable to spontaneously generate a pressure difference between the lower chamber 11 and the upper chamber 12, facilitating the plasma to pass through the through holes 133. However, the present disclosure is not limited thereto. In some embodiments of the present disclosure, the plasma may pass through the through holes only under the influence of gravity.

In this embodiment, the dielectric material layer 131 and the plasma may have the same metal material or the same metal oxide material. Therefore, even if the plasma etches the dielectric material layer 131 due to insufficient neutralization, it would not cause heterogeneous interference with the deposition onto the sample. For example, in order to deposit an aluminum oxide layer onto the sample, a precursor that has aluminum (aluminum elements or aluminum ions) and can be excited to be plasma can be selected, and aluminum oxide can also be used as the dielectric material of the dielectric material layer 131.

In this embodiment, the metal material layer 132 can exhibit a self-bias effect. Therefore, it is favorable to enhance electric neutrality of the plasma. However, the present disclosure is not limited thereto. In some embodiments of the present disclosure, an external bias voltage can also be applied to the metal material layer to achieve the desired bias effect.

In some embodiments of the present disclosure, the dispensing plate is detachably disposed between the lower chamber and the upper chamber. This allows for easy replacement of the dispensing plate when the dispensing plate becomes unusable due to reasons such as operation error. However, the present disclosure it not limited to the detachability of the dispensing plate.

To use the plasma processing apparatus 1 of one embodiment of the present disclosure, a sample can first be placed in the lower chamber 11. After the extractor pump 14 is turned on, plasma can be excited from a precursor in the upper chamber 12 and then can pass through the through holes 133 to be deposited onto the sample. After the deposition is completed, the extractor pump 14 can be turned off, and then the deposited finished product can be removed from the lower chamber 11.

According to the plasma processing apparatus discussed above, with proper size arrangement of the dispensing plate, it is favorable to uniformly deposit the plasma exiting from the upper chamber onto the sample in the lower chamber.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

What is claimed is:

1. A plasma processing apparatus comprising:
a lower chamber configured for a sample to be placed therein;
an upper chamber located above the lower chamber, wherein the upper chamber is configured to accommodate a plasma; and
a dispensing plate disposed between the lower chamber and the upper chamber, the dispensing plate comprising:
a dielectric material layer;
a metal material layer disposed on a side of the dielectric material layer close to the lower chamber; and
at least one through hole arranged through the dielectric material layer and the metal material layer along a longitudinal direction, wherein the at least one through hole is in fluid communication connection with the lower chamber and the upper chamber, and the at least one through hole is configured for the plasma passing therethrough to be deposited onto the sample;
wherein a first thickness of the dielectric material layer along the longitudinal direction is defined as T1, a second thickness of the metal material layer along the longitudinal direction is defined as T2, a diameter of the at least one through hole is defined as D1, and the following condition is satisfied:
$$5 \leq ( T 1 + T 2 ) / D 1.$$

2. The plasma processing apparatus according to claim 1, wherein the first thickness is defined as T1, the second thickness is defined as T2, the diameter is defined as D1, and the following condition is satisfied:
$$5 \leq ( T 1 + T 2 ) / D 1 \leq 20 .$$

3. The plasma processing apparatus according to claim 1, wherein the first thickness is defined as T1, the second thickness is defined as T2, and the following condition is satisfied:
$$T 1 \leq T 2.$$

4. The plasma processing apparatus according to claim 1, wherein the first thickness is defined as T1, the diameter is defined as D1, and the following condition is satisfied:
$$D 1 \leq 10 \times T 1.$$

5. The plasma processing apparatus according to claim 1, wherein an angle between the longitudinal direction and an extension direction of the dielectric material layer is defined as θ, and the following condition is satisfied:
$$7 {5}^{°} \leq θ \leq 10 {5}^{°} .$$

6. The plasma processing apparatus according to claim 5, wherein the angle between the longitudinal direction and the extension direction is defined as θ, and the following condition is satisfied:
$$θ = 9 {0}^{°} .$$

7. The plasma processing apparatus according to claim 1, wherein a quantity of the at least one through hole is plural, the diameter of each of the through holes is defined as D1, an interval distance between adjacent two of the through holes is defined as D2, and the following condition is satisfied:
$$D 2 \leq 20 \times D 1 .$$

8. The plasma processing apparatus according to claim 7, wherein a ratio of a sum of areas of the through holes to an area of the dielectric material layer ranges from 15% to 40%.

9. The plasma processing apparatus according to claim 1, further comprising an extractor pump in fluid communication connection with the lower chamber for extracting air from the lower chamber.

10. The plasma processing apparatus according to claim 1, wherein the dielectric material layer and the plasma have a same metal material or a same metal oxide material.

11. The plasma processing apparatus according to claim 1, wherein the dispensing plate is in a disc shape.
